(19) United States
(12) Patent Application Publication
(10) Pub. No.: US 2018/0033907 A1
(43) Pub. Date: Feb. 1, 2018

(54) NITRIDE SEMICONDUCTOR TEMPLATE AND METHOD FOR MANUFACTURING SAME

(71) Applicants: Yoshikatsu MORISHIMA, Tokyo (JP); Kazuyuki IIZUKA, Tokyo (JP); Akito KURAMATA, Tokyo (JP); Hideki HIRAYAMA, Saitama (JP)

(72) Inventors: Yoshikatsu MORISHIMA, Tokyo (JP); Kazuyuki IIZUKA, Tokyo (JP); Akito KURAMATA, Tokyo (JP); Hideki HIRAYAMA, Saitama (JP)

(73) Assignees: TAMURA CORPORATION, Tokyo (JP); RIKEN, Saitama (JP)

(21) Appl. No.: 15/551,960

(22) PCT Filed: Feb. 8, 2016
(86) PCT No.: PCT/JP2016/053695

§ 371 Date: Aug. 18, 2017

(30) Foreign Application Priority Data
Feb. 25, 2015 (JP) 2015-035895

(51) Int. Cl. H01L 33/00; C30B 29/40; H01L 33/32; C30B 25/18; H01L 33/02; H01L 33/12; C30B 29/16; C30B 29/68

(52) U.S. Cl. CPC H01L 33/007; C30B 29/16; C30B 29/406; C30B 29/68; C30B 25/183; H01L 33/025; H01L 33/12; H01L 33/32

(57) ABSTRACT

A nitride semiconductor template includes a Ga₂O₃ substrate, a buffer layer formed on the Ga₂O₃ substrate and including AlN as a principal component, a first nitride semiconductor layer formed on the buffer layer and including AlₓGa₁₋ₓN (0.2<x≦1) as a principal component, and a second nitride semiconductor layer formed on the first nitride semiconductor layer and including Al_{y}Ga_{1-y}N (0.2≦y≦0.55, y<x) as a principal component.

### TECHNICAL FIELD

The invention relates to a nitride semiconductor template and a method for manufacturing the nitride semiconductor template.

### BACKGROUND ART

A nitride semiconductor template is known in which a nitride semiconductor layer is formed on a Ga₂O₃ substrate via an AlN buffer layer (see, e.g., PTL 1)

According to PTL 1, appropriately selecting a plane orientation of a main surface of the Ga₂O₃ substrate allows the nitride semiconductor layer to have a mirror surface.

### CITATION LIST

### Patent Literature

[PTL 1]

JP-A 2014-199935

### SUMMARY OF INVENTION

### Technical Problem

When forming a nitride semiconductor on the Ga₂O₃ substrate, however, the conditions to prevent pits or cracks on the nitride semiconductor are different depending on the amount of the Al composition of the nitride semiconductor. Therefore, the optimal method needs to be chosen for each composition to obtain a higher-quality nitride semiconductor.

In recent years, ultraviolet LEDs in the wavelength range of 315 to 360 nm have been developed as an alternative to high-pressure mercury lamps used for curing, etc.

It is an object of the invention to provide a transparent nitride semiconductor template that includes a high-quality nitride semiconductor, is suitable for use in an ultraviolet LED and has an electrical conductivity, as well as a manufacturing method that allows simple manufacture of the transparent nitride semiconductor template.

### Solution to Problem

To achieve the above-mentioned object, an aspect of the invention provides a nitride semiconductor template described in the following [1] to [5] and a method for manufacturing a nitride semiconductor template described in the following [6] to [8].

A nitride semiconductor template, comprising: a Ga₂O₃ substrate; a buffer layer formed on the Ga₂O₃ substrate and comprising AlN as a principal component; a first nitride semiconductor layer formed on the buffer layer and comprising AlₓGa₁₋ₓN (0.2<x≦1) as a principal component; and a second nitride semiconductor layer formed on the first nitride semiconductor layer and comprising Al_{y}Ga_{1-y}N (0.2≦y≦0.55, y<x) as a principal component.

The nitride semiconductor template described in [1], wherein the buffer layer is not more than 10 nm in thickness.

The nitride semiconductor template described in [1] or [2], wherein the second nitride semiconductor layer has no crack on a surface thereof.

The nitride semiconductor template described in [1] or [2], wherein the second nitride semiconductor layer has no pit on a surface thereof.

The nitride semiconductor template described in [1] or [2], wherein the second nitride semiconductor layer has a dislocation density of not more than 2.0×10¹⁰ cm⁻².

A method for manufacturing a nitride semiconductor template, comprising: a step of forming a Ga₂O₃ substrate; a step of forming a buffer layer comprising AlN as a principal component on the Ga₂O₃ substrate; a step of forming a first nitride semiconductor layer comprising AlₓGa₁₋ₓN (0.2<x≦1) as a principal component on the buffer layer; and a step of forming a second nitride semiconductor layer comprising Al_{y}Ga_{1-y}N (0.2≦y≦0.55, y<x) as a principal component on the first nitride semiconductor layer.

The method for manufacturing a nitride semiconductor template described in [6], wherein the buffer layer is not more than 10 nm in thickness.

The method for manufacturing a nitride semiconductor template described in [6] or [7], wherein a growth temperature of the second nitride semiconductor layer is more than 1100° C., and a growth temperature of the first nitride semiconductor layer is less than 1100° C.

### Advantageous Effects of Invention

According to the invention, a transparent nitride semiconductor template can be provided that includes a high-quality nitride semiconductor, is suitable for use in an ultraviolet LED and has electrical conductivity, as well as a manufacturing method that allows simple manufacture of the transparent nitride semiconductor template.

### BRIEF DESCRIPTION OF DRAWINGS

FIG. 1 is a vertical cross-sectional view showing a nitride semiconductor template in an embodiment.

FIG. 2A is an image of a surface of a second nitride semiconductor layer of Sample 1 observed under an optical microscope.

FIG. 2B is an image of a surface of a second nitride semiconductor layer of Sample 4 observed under an optical microscope.

FIG. 2C is an image of a surface of a second nitride semiconductor layer of Sample 5 observed under an optical microscope.

FIG. 3 is an X-ray diffraction pattern of the nitride semiconductor template as Sample 5 obtained using a symmetrical reflection method.

FIG. 4 shows photoluminescence spectra of the nitride semiconductor template as Sample 5.

### DESCRIPTION OF EMBODIMENT

### Embodiment

(Structure of Nitride Semiconductor Template)

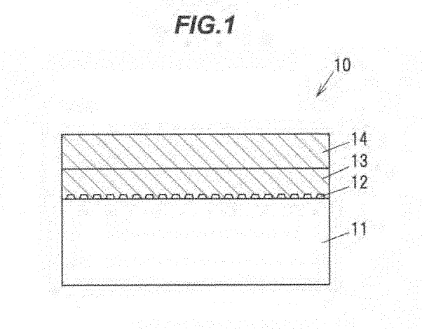

FIG. 1 is a vertical cross-sectional view showing a nitride semiconductor template 10 in the embodiment. The nitride semiconductor template 10 is a template suitable for use in an ultraviolet LED with an emission wavelength of 315 to 360 nm.

The nitride semiconductor template 10 includes a Ga₂O₃ substrate 11, a buffer layer 12 on the Ga₂O₃ substrate 11, a first nitride semiconductor layer 13 on the buffer layer 12, and a second nitride semiconductor layer 14 on the first nitride semiconductor layer 13.

The Ga₂O₃ substrate 11 is formed of a β-Ga₂O₃ single crystal. The main surface of the Ga₂O₃ substrate 11 is a (−201) plane, a (101) plane, a (310) plane, a (3-10) plane or planes inclined from these planes within a range of about ±2°, which can be a base for growth of high-quality nitride semiconductor crystal. The Ga₂O₃ substrate 11 is, e.g., a circular substrate having a diameter of 50.8 mm (2 inches), but the shape and size thereof are not limited.

Since Ga₂O₃ hardly absorbs light with a wavelength of 315 to 360 nm, the Ga₂O₃ substrate 11 is excellent as a substrate of the nitride semiconductor template 10 which is used to form an UV LED with an emission wavelength of 315 to 360 nm. By contrast, e.g., GaN absorbs light with a wavelength of 315 to 360 nm well. Therefore, GaN substrates are not suitable as UV LED templates, and to prevent a decrease in light extraction efficiency, the GaN substrates need to be removed after manufacturing LEDs.

In addition, the Ga₂O₃ substrate 11, which contains a dopant such as Si or Sn and has excellent conductivity, is excellent as an LED substrate. On the other hand, in case that a low-conductivity substrate, e.g., a sapphire substrate, is used, it is not possible to form vertical-type LEDs, and horizontal-type LEDs, even when formed, have high electrical resistance since an electric current flows through a thin nitride semiconductor layer on the substrate.

The buffer layer 12 is formed of a crystal consisting mainly of AlN. The buffer layer 12 may partially cover the upper surface of the Ga₂O₃ substrate 11 as shown in FIG. 1, or may cover the entire upper surface. To obtain higher crystal quality, the thickness of the buffer layer 12 is preferably not more than 10 nm, more preferably, not more than 5 nm.

The second nitride semiconductor layer 14 is used as a cladding layer in a UV LED which is formed using the nitride semiconductor template 10. To form a UV LED with an emission wavelength of 315 to 360 nm, the second nitride semiconductor layer 14 to be a cladding layer need to have a composition roughly represented by Al_{y}Ga_{1-y}N (0.2≦y≦0.55).

The Al composition of the first nitride semiconductor layer 13 is greater than that of the second nitride semiconductor layer 14. In other words, the composition of the first nitride semiconductor layer 13 is expressed by AlₓGa₁₋ₓN (0.2<x≦1), and the Al composition-x of the first nitride semiconductor layer 13 and the Al composition-y of the second nitride semiconductor layer 14 satisfy the relation of y<x. The first nitride semiconductor layer 13 having such a composition allows the second nitride semiconductor layer 14 to have a mirror surface and generation of cracks and pits to be suppressed.

The first nitride semiconductor layer 13 and the second nitride semiconductor layer 14 may contain a dopant such as Si. The thickness of the first nitride semiconductor layer 13 is, e.g., 100 to 300 nm. The thickness of the second nitride semiconductor layer 14 is, e.g., 1 to 2μm.

The surface of the second nitride semiconductor layer 14 is a mirror surface and hardly contains, or does not contain cracks and pits (hole-like defects) at all.

If the second nitride semiconductor layer 14 is formed on the buffer layer 12 without providing the first nitride semiconductor layer 13, cracks are generated on the surface of the second nitride semiconductor layer 14. Meanwhile, when only the first nitride semiconductor layer 13 is formed on the buffer layer 12 without providing the second nitride semiconductor layer 14, a mirror surface cannot be obtained.

(Method for Manufacturing Nitride Semiconductor Template)

An example method for manufacturing the nitride semiconductor template 10 will be described below.

Firstly, the Ga₂O₃ substrate 11 treated by CMP (Chemical Mechanical Polishing) is cleaned with an organic solvent and SPM (Sulfuric acid/hydrogen peroxide mixture).

Next, the Ga₂O₃ substrate 11 is conveyed to a chamber of a MOCVD (Metal Organic Chemical Vapor Deposition) apparatus.

Next, the buffer layer 12 is formed on the Ga₂O₃ substrate 11. An AlN crystal is grown on the Ga₂O₃ substrate 11 by supplying source gases and N₂ gas as a carrier gas into the chamber in a state that the temperature inside the chamber is maintained at 400 to 600° C., thereby forming the buffer layer 12 in the form of film.

The source gases used to form the buffer layer 12 are, e.g., trimethylaluminum (TMA) gas as an Al source and NH₃ gas as an N source. The carrier gas may be alternatively H₂ gas, etc.

Next, the first nitride semiconductor layer 13 is formed on the buffer layer 12. In detail, for example, source gases for the first nitride semiconductor layer 13 and H₂ gas as a carrier gas are supplied into the chamber with pressure maintained at 100 mbar and temperature maintained at not less than 885° C., thereby growing the first nitride semiconductor layer 13.

The source gases used to form the nitride semiconductor layer 13 are, e.g., trimethylaluminum (TMA) gas as an Al source, trimethylgallium (TMG) gas as Ga source and NH₃ gas as an N source. The carrier gas may be alternatively N₂ gas, etc.

Next, the second nitride semiconductor layer 14 is formed on the first nitride semiconductor layer 13. In detail, for example, source gases for the second nitride semiconductor layer 14 and H₂ gas as a carrier gas are supplied into the chamber with temperature maintained at not less than 1100° C., thereby growing the second nitride semiconductor layer 14.

Here, generation of pits can be suppressed when the second nitride semiconductor layer 14 is grown at a growth temperature of more than 1100° C. Furthermore, generation of pits can be suppressed more reliably when the second nitride semiconductor layer 14 is grown at a growth temperature of not less than 1120° C.

The source gases for the second nitride semiconductor layer 14 may be the same as those for the first nitride semiconductor layer 13. The carrier gas may be alternatively N₂ gas, etc.

(Evaluation of Surface State of Second Nitride Semiconductor Layer)

Table 1 below shows the growth conditions of each layer and the results of evaluating the surface state of the second nitride semiconductor layers.

Each of the Ga₂O₃ substrates of seven types of nitride semiconductor templates (Samples 1 to 7) used for evaluation was a 2 inch-diameter circular substrate having a (−201) plane as the main surface. Trimethylaluminum (TMA) gas, trimethylgallium (TMG) gas and NH₃ gas were respectively used as the Al source, the Ga source and the N source for the first and second nitride semiconductor layers.

TABLE 1

| | | | First nitride | | Second nitride | | | | |
|---|---|---|---|---|---|---|---|---|---|
| | Buffer layer | | semiconductor layer | | semiconductor layer | | Surface state | | |
| Sam- | Film | Growth | | Growth | | Growth | Check of | | |
| ple | thickness | temperature | | temperature | | temperature | etched Ga₂O₃ | | |
| No. | [nm] | [° C.] | Composition | [° C.] | Composition | [° C.] | substrate | Pit | Crack |
| 1 | 5 | 550 | N/A | N/A | Al_{0.3}Ga_{0.7}N | 1100 | Etched | Observed | Observed |
| 2 | 5 | 800 | N/A | N/A | Al_{0.3}Ga_{0.7}N | 1100 | Etched | Observed | Observed |
| 3 | 5 | 550 | Al_{0.3}Ga_{0.7}N | 1020 | Al_{0.3}Ga_{0.7}N | 1100 | Not etched | Observed | Observed |
| 4 | 5 | 550 | AlN | 1020 | Al_{0.3}Ga_{0.7}N | 1100 | Not etched | Observed | Not observed |
| 5 | 5 | 550 | AlN | 1020 | Al_{0.3}Ga_{0.7}N | 1120 | Not etched | Not observed | Not observed |
| 6 | 5 | 550 | Al_{0.8}Ga_{0.2}N | 1020 | Al_{0.3}Ga_{0.7}N | 1120 | Not etched | Not observed | Not observed |
| 7 | 5 | 550 | Al_{0.8}Ga_{0.2}N | 1020 | Al_{0.45}Ga_{0.55}N | 1120 | Not etched | Not observed | Not observed |

The second nitride semiconductor layer of each of Samples 1 to 7 was grown at a growth rate of 2 μm/h.

In Samples 1 and 2, the second nitride semiconductor layer was directly formed on the buffer layer without forming the first nitride semiconductor layer. Pits and cracks were generated on the surface of the second nitride semiconductor layer of Sample 1 and a mirror surface was obtained only in a 25 mm-diameter region. Likewise, pits and cracks were generated also on the surface of the second nitride semiconductor layer of Sample 2. It is considered that this is because the first nitride semiconductor layer was not formed.

Meanwhile, in Sample 1, the Ga₂O₃ substrate was partially etched. The reason is considered as follows: since the second nitride semiconductor layer to be grown at a higher temperature than the first nitride semiconductor layer was directly formed on the buffer layer, the buffer layer migrated (or crystallized) too much and thus did not sufficiently protect some portion of the surface of the Ga₂O₃ substrate. On the other hand, in Sample 2, the Ga₂O₃ substrate was etched when forming the buffer layer since the growth temperature of the buffer layer was too high.

In Sample 3, cracks were generated on the surface of the second nitride semiconductor layer. It is considered that this is because the Al composition of the first nitride semiconductor layer was the same as that of the second nitride semiconductor layer.

In Sample 4, pits were generated on the surface of the second nitride semiconductor layer. It is considered that this is because growth of the crystal in the lateral direction was insufficient when the second nitride semiconductor layer was grown at a temperature of 1100° C.

In Sample 5, none of cracks and pits were generated on the surface of the second nitride semiconductor layer. It is considered that this is mainly because the first and second nitride semiconductor layers were both formed and the Al composition of the second nitride semiconductor layer was smaller than that of the first nitride semiconductor layer. The reason why pits were not generated is considered that the second nitride semiconductor layer was grown at a temperature of 1120° C., i.e., higher than 1100° C.

Sample 6 was the same as Sample 5, except that the material of the first nitride semiconductor layer was changed to Al_{0.8}Ga_{0.2}N from AlN to decrease electrical resistance of the first nitride semiconductor layer. Also in Sample 6, none of cracks and pits were generated.

In Sample 7, the Al composition of the second nitride semiconductor layer was increased to more than that of Samples 5 and 6 for use in LEDs with a short wavelength. Also in Sample 7, none of cracks and pits were generated.

In all of Samples 1 to 7, dislocation density in the second nitride semiconductor layer was suppressed to not more than 2.0×10¹⁰ cm⁻².

It is understood from the evaluation results of Samples 1 to 7 that the conditions to obtain the second nitride semiconductor layer with a good surface state are that the first and second nitride semiconductor layers are both formed, that the Al composition of the second nitride semiconductor layer is smaller than that of the first nitride semiconductor layer, and that the growth temperature of the second nitride semiconductor layer is more than 1100° C.

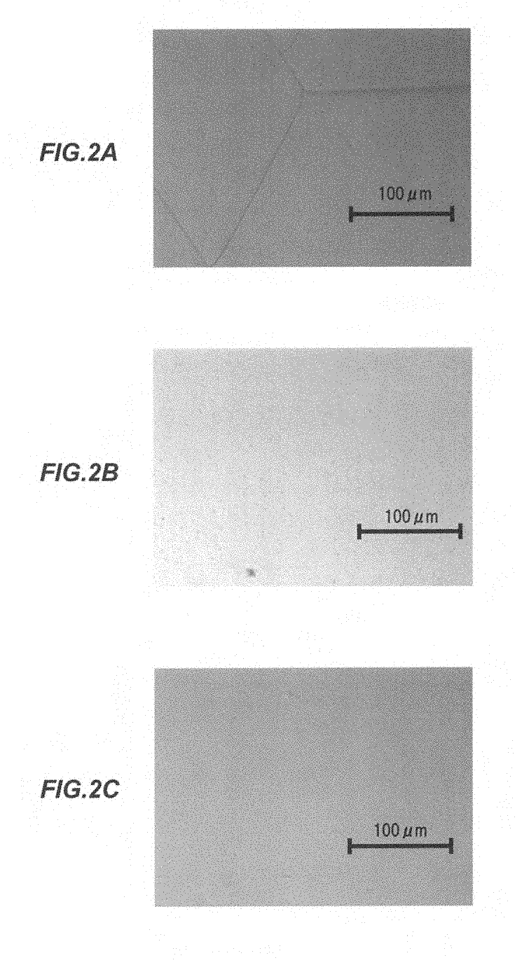

FIGS. 2A, 2B and 2C are images of the surfaces of the respective second nitride semiconductor layers of Samples 1, 4 and 5 observed under an optical microscope. As shown in Table 1, cracks are observed on the surface of the second nitride semiconductor layer of Sample 1 shown in FIG. 2A, and pits are observed on the surface of the second nitride semiconductor layer of Sample 4 shown in FIG. 2B. On the other hand, none of cracks and pits are observed on the surface of the second nitride semiconductor layer of Sample 5 shown in FIG. 2C.

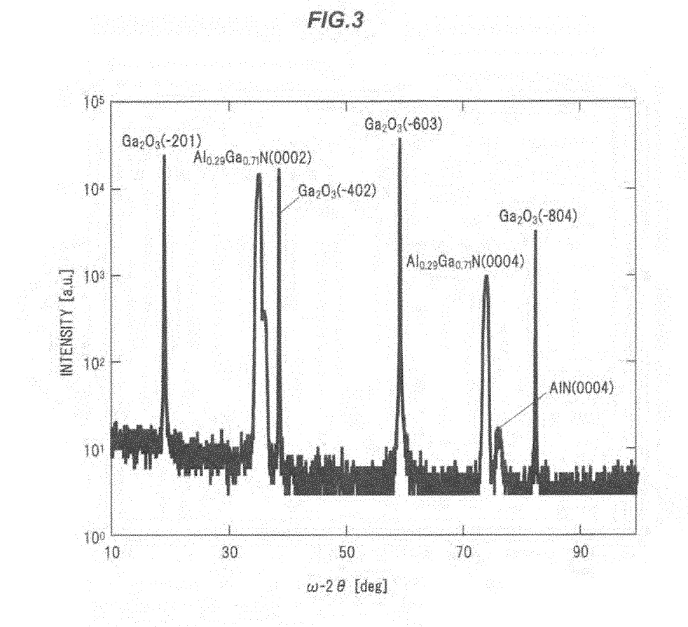

FIG. 3 is an X-ray diffraction pattern of the nitride semiconductor template as Sample 5.

The X-ray diffraction pattern in FIG. 3 only has peaks of diffraction from the Ga₂O₃ substrate at a (−201) plane and planes parallel to the (−201) plane, from AlN as the first nitride semiconductor layer at a plane parallel to a (0001) plane and from Al_{0.3}Ga_{0.7}N as the second nitride semiconductor layer at planes parallel to a (0001) plane, and shows that the second nitride semiconductor layer does not have a phase grown in a different direction. Note that, the Al composition is shown as Al_{0.29}Ga_{0.71}N in FIG. 3 since the Al composition of Al_{0.3}Ga_{0.7}N was actually 0.29 as a result of calculation based on complete lattice relaxation derived from the peak position.

Meanwhile, as a result of x-ray rocking curve measurement on the nitride semiconductor template as Sample 5, the full width at half maximum of diffraction peak from a (0002) plane was 1164 arcseconds and the full width at half maximum of diffraction peak from a (1-102) plane was 1536 arcseconds.

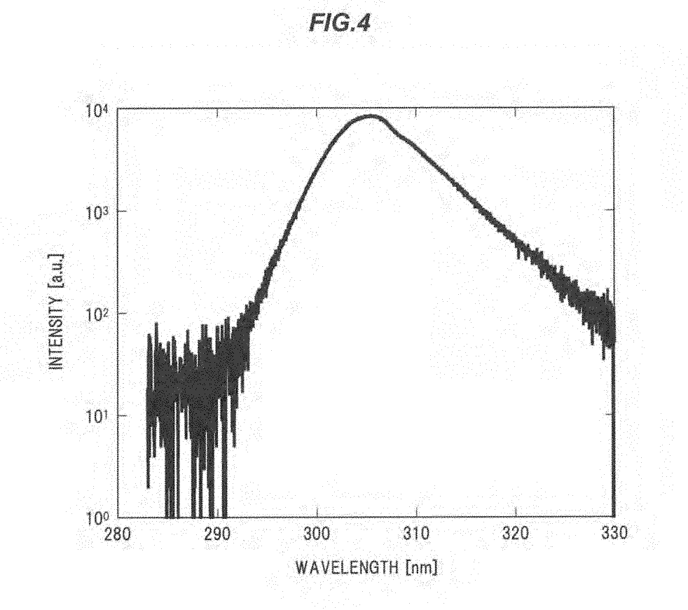

FIG. 4 shows photoluminescence spectra of the nitride semiconductor template as Sample 5. This spectrum was obtained by photoluminescence measurement using excitation light with a wavelength of 244 nm at room temperature, and the peak at a wavelength of 305 nm probably due to band edge emission is shown as a main peak.

(Effects of the Embodiment)

In the embodiment, it is possible to obtain a nitride semiconductor template which has a high-quality nitride semiconductor on a Ga₂O₃ substrate and is suitable for use in a UV LED with an emission wavelength of 315 to 360 nm.

Although the embodiment of the invention has been described, the invention is not intended to be limited to the embodiment, and the various kinds of modifications can be implemented without departing from the gist of the invention.

In addition, the invention according to claims is not to be limited to embodiment. Further, it should be noted that all combinations of the features described in the embodiment are not necessary to solve the problem of the invention.

### INDUSTRIAL APPLICABILITY

Provided is a transparent nitride semiconductor template that includes a high-quality nitride semiconductor, is suitable for use in an ultraviolet LED and has electrical conductivity, as well as a manufacturing method that allows simple manufacture of the transparent nitride semiconductor template.

### REFERENCE SIGNS LIST

10 NITRIDE SEMICONDUCTOR TEMPLATE

11 Ga₂O₃ SUBSTRATE

12 BUFFER LAYER

13 FIRST NITRIDE SEMICONDUCTOR LAYER

14 SECOND NITRIDE SEMICONDUCTOR LAYER

1. A nitride semiconductor template, comprising:
a Ga₂O₃ substrate;
a buffer layer formed on the Ga₂O₃ substrate and comprising AlN as a principal component;
a first nitride semiconductor layer formed on the buffer layer and comprising AlₓGa₁₋ₓN (0.2<x≦1) as a principal component; and
a second nitride semiconductor layer formed on the first nitride semiconductor layer and comprising Al_{y}Ga_{1-y}N (0.2≦y≦0.55, y<x) as a principal component.

2. The nitride semiconductor template according to claim 1, wherein the buffer layer is not more than 10 nm in thickness.

3. The nitride semiconductor template according to claim 1, wherein the second nitride semiconductor layer has no crack on a surface thereof.

4. The nitride semiconductor template according to claim 1, wherein the second nitride semiconductor layer has no pit on a surface thereof.

5. The nitride semiconductor template according to claim 1, wherein the second nitride semiconductor layer has a dislocation density of not more than 2.0×10¹⁰ cm⁻².

6. A method for manufacturing a nitride semiconductor template, comprising:
a step of forming a Ga₂O₃ substrate;
a step of forming a buffer layer comprising AlN as a principal component on the Ga₂O₃ substrate;
a step of forming a first nitride semiconductor layer comprising AlₓGa₁₋ₓN (0.2<x≦1) as a principal component on the buffer layer; and
a step of forming a second nitride semiconductor layer comprising Al_{y}Ga_{1-y}N (0.2≦y≦0.55, y<x) as a principal component on the first nitride semiconductor layer.

7. The method for manufacturing a nitride semiconductor template according to claim 6, wherein the buffer layer is not more than 10 nm in thickness.

8. The method for manufacturing a nitride semiconductor template according to claim 6, wherein a growth temperature of the second nitride semiconductor layer is more than 1100° C., and a growth temperature of the first nitride semiconductor layer is less than 1100° C.

9. The nitride semiconductor template according to claim 2, wherein the second nitride semiconductor layer has no crack on a surface thereof.

10. The nitride semiconductor template according to claim 2, wherein the second nitride semiconductor layer has no pit on a surface thereof.

11. The nitride semiconductor template according to claim 2, wherein the second nitride semiconductor layer has a dislocation density of not more than 2.0×10¹⁰ cm⁻².

12. The method for manufacturing a nitride semiconductor template according to claim 7, wherein a growth temperature of the second nitride semiconductor layer is more than 1100° C., and a growth temperature of the first nitride semiconductor layer is less than 1100° C.
